(19) United States
(12) Patent Application Publication
(10) Pub. No.: US 2012/0292587 A1
(43) Pub. Date: Nov. 22, 2012

(54) NONVOLATILE MEMORY DEVICE

(75) Inventors: Kouji MATSUO, Kanagawa-ken (JP); Noritake OHMACHI, Tokyo (JP); Tomotaka ARIGA, Kanagawa-ken (JP); Junichi WADA, Kanagawa-ken (JP); Yoshio OZAWA, Kanagawa-ken (JP)

(73) Assignee: Kabushiki Kaisha Toshiba, Tokyo (JP)

(21) Appl. No.: 13/424,880

(22) Filed: Mar. 20, 2012

(30) Foreign Application Priority Data
May 16, 2011 (JP) 2011-109936

(51) Int. Cl. H01L 47/00

(52) U.S. Cl. 257/4; 257/E47.001

(57) ABSTRACT

According to one embodiment, a nonvolatile memory device includes a memory cell. The memory cell includes a stacked film structure. The stacked film structure is capable of maintaining a first state or a second state. The first state includes a lower electrode film, a first memory element film provided on the lower electrode film and containing a first oxide and an upper electrode film provided on the first memory element film. The second state includes the lower electrode film, the first memory element film provided on the lower electrode film, a second memory element film provided on the first memory element film and containing a second oxide and the upper electrode film provided on the second memory element film.

### CROSS-REFERENCE TO RELATED APPLICATIONS

This application is based upon and claims the benefit of priority from the prior Japanese Patent Application No. 2011-109936, filed on May 16, 2011; the entire contents of which are incorporated herein by reference.

### FIELD

Embodiments described herein relate generally to a nonvolatile memory device.

### BACKGROUND

To increase the integration degree of nonvolatile memory devices, three-dimensional memory cells are drawing attention. Among them, resistance variable memory cells are investigated. Examples of the resistance variable memory cell include one in which a filament is formed in a resistance variable film in a memory cell. In this kind of memory cell, the resistance variable film (e.g. a metal oxide film) is interposed between anode and cathode. The filament that forms a fine conductive region is formed in the metal oxide film. The filament is formed by applying a voltage large enough to break the breakdown voltage of the metal oxide film between anode and cathode. That is, when a prescribed voltage is applied, an electric field concentration occurs in part of the metal oxide film to form a filament-like conductive path in the metal oxide film. Thereby, the memory cell changes from a high resistance state to a low resistance state. At this time, the conductive path is presumed to be in a state where the oxygen bond of the metal oxide is cut off. It is presumed that, in the conductive path, electrons move more easily than in the portion other than the conductive path and consequently a low resistive state is kept.

After that, a voltage is applied again to move oxygen to the anode side and the recoupling of oxygen is performed on the metal oxide film near the interface between the anode and the metal oxide film. Thereby, the memory cell can be transitioned from the low resistance state to the high resistance state again. Subsequently, by applying a reverse voltage between anode and cathode, the oxygen ions that have moved are returned to the previous positions, and thereby the memory cell transitions from the high resistance state to the low resistance state. Thereby, the memory cell can repeat the low resistance state and the high resistance state.

However, the formation of a filament depends on a stochastic method in which part of a metal oxide film is broken. Hence, the metal oxide film is less likely to have a fixed breakdown voltage. Therefore, the level of filament formation may vary between memory cells. To avoid this, a method may be used in which such a high voltage as can form a filament in any metal oxide film is applied to collectively form filaments in all the memory cells. However, in the method, some memory cells may be broken or the filament itself may become excessively large to increase power consumption significantly. Also a method may be used in which a filament is formed by increasing the voltage gradually to a voltage at which a voltage breakdown occurs so that a filament may be gradually formed. However, in the method, a large amount of manufacturing time is required. Thus, nonvolatile memory devices using a filament are not low cost, and not good in productivity, either.

### BRIEF DESCRIPTION OF THE DRAWINGS

FIGS. 1A and 1B are schematic cross-sectional views of a memory cell of a nonvolatile memory device according to a first embodiment;

FIG. 2 is a graph showing the absolute value of the standard Gibbs free energy of formation per one oxygen atom of each of a plurality of metal oxides;

FIGS. 3A and 3B are schematic cross-sectional views of a memory cell of a nonvolatile memory device according to a second embodiment;

FIGS. 4A to 4D are schematic cross-sectional views for describing an example of the operation of a memory cell in which the electric field control film is not provided;

FIGS. 5A and 5B are schematic diagrams of the energy band structure of the memory cell according to the second embodiment;

FIGS. 6A and 6B are schematic diagrams of the energy band structure in the operation of the memory cell according to the second embodiment;

FIG. 7 is the simulation results of the current-voltage characteristics of the memory cell;

FIG. 8 is a list of the absolute value of the standard Gibbs free energy of formation, the absolute value of the standard Gibbs free energy of formation per one oxygen atom, and the energy gap of each of a plurality of metal oxides;

FIGS. 9A and 9B are schematic cross-sectional views of a memory cell of a nonvolatile memory device according to a third embodiment;

FIGS. 10A to 10C are schematic cross-sectional views of a memory cell of a nonvolatile memory device according to a fourth embodiment;

FIGS. 11A to 11E are schematic cross-sectional views for describing a defective formation of the second memory element film;

FIGS. 12A and 12B are schematic cross-sectional views of a memory cell of a nonvolatile memory device according to a fifth embodiment;

FIGS. 13A and 13B are views for describing the current-voltage characteristics of the memory cell;

FIG. 14 is a schematic cross-sectional view of a memory cell of a nonvolatile memory device according to a sixth embodiment;

FIGS. 15A to 15C are schematic cross-sectional views for describing the operation of the memory cell according to the sixth embodiment;

FIGS. 16A to 16D are schematic cross-sectional views for describing the operation of the memory cell according to the sixth embodiment;

FIGS. 17A and 17B show the structure of a memory cell array of a nonvolatile memory device in which any of the memory cells 100 to 105 described above is mounted; and

FIGS. 18A and 18B show another structure of the memory cell array in which the memory cell 101 is mounted.

### DETAILED DESCRIPTION

In general, according to one embodiment, a nonvolatile memory device includes a memory cell. The memory cell includes a stacked film structure. The stacked film structure is capable of maintaining a first state or a second state. The first state includes a lower electrode film, a first memory element film provided on the lower electrode film and containing a first oxide and an upper electrode film provided on the first memory element film. The second state includes the lower electrode film, the first memory element film provided on the lower electrode film, a second memory element film provided on the first memory element film and containing a second oxide and the upper electrode film provided on the second memory element film. An absolute value of a standard Gibbs free energy of formation per one oxygen atom when the lower electrode film or the upper electrode film changes into an oxide film is smaller than an absolute value of a standard Gibbs free energy of formation per one oxygen atom of the first oxide contained in the first memory element film. An absolute value of a standard Gibbs free energy of formation per one oxygen atom of the second oxide contained in the second memory element film is larger than an absolute value of a standard Gibbs free energy of formation per one oxygen atom when the upper electrode film changes into the oxide film. A concentration of oxygen contained in the second memory element film is higher than a concentration of oxygen contained in the first memory element film. A resistance between the lower electrode film and the upper electrode film in the second state is higher than a resistance between the lower electrode film and the upper electrode film in the first state.

Various embodiments will be described hereinafter with reference to the accompanying drawings.

Hereinbelow, embodiments are described with reference to the drawings. In the following description, identical components are marked with the same reference numerals, and a description of components once described is omitted as appropriate. The embodiments described below are not necessarily independent of one another but may be appropriately combined.

### First Embodiment

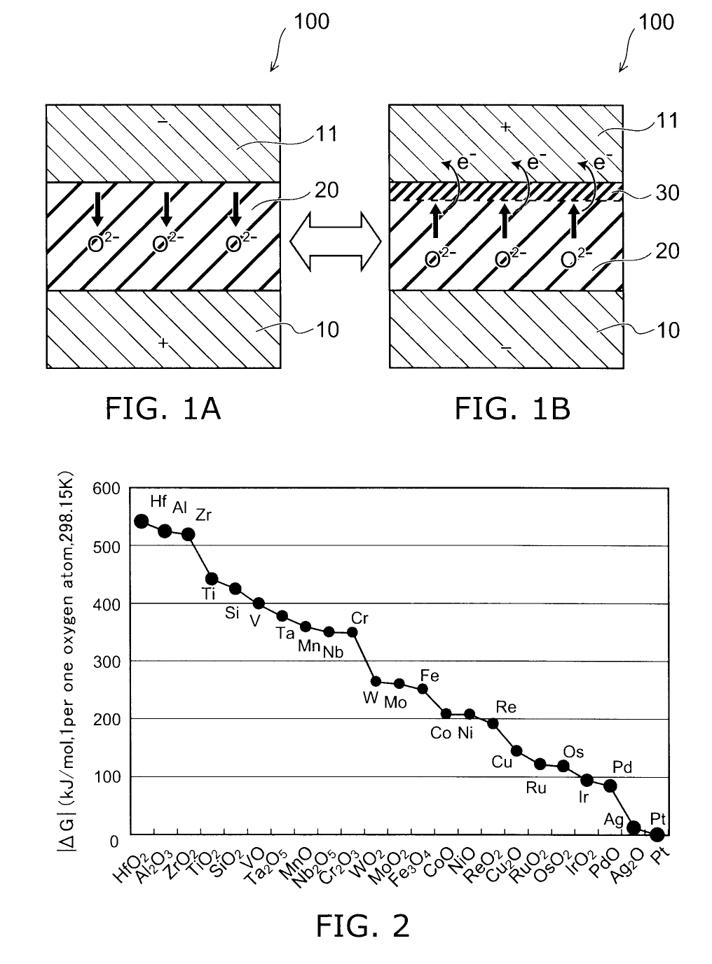

FIGS. 1A and 1B are schematic cross-sectional views of a memory cell of a nonvolatile memory device according to a first embodiment.

A memory cell 100 of a nonvolatile memory device according to the first embodiment is a resistance variable memory cell and includes a stacked film structure. The memory cell 100 can maintain a first state shown in FIG. 1A or a second state shown in FIG. 1B. FIG. 1A shows the state after the setting of the memory cell 100, and FIG. 1B shows the state after the resetting of the memory cell 100.

In the first state shown in FIG. 1A, the memory cell 100 includes a lower electrode film 10, a first memory element film 20 provided on the lower electrode film 10 and containing an oxide (a first oxide), and an upper electrode film 11 provided on the first memory element film 20. The first memory element film 20 contains an oxide of one or more kinds of metal elements.

In the second state shown in FIG. 1B, the memory cell 100 includes the lower electrode film 10, the first memory element film 20 provided on the lower electrode film 10, a second memory element film (a high resistance layer) 30 provided on the first memory element film 20 and containing an oxide (a second oxide), and the upper electrode film 11 provided on the second memory element film 30. Although the first memory element film 20 in the second state is indicated by the same reference numeral as that in the first state, actually when the condition is transitioned from the first state to the second state, oxygen moves from the first memory element film 20 to the second memory element film (described later). Therefore, the oxygen concentration of the first memory element film 20 in the second state is lower than the oxygen concentration of the first memory element film 20 in the first state.

The oxide contained in the first memory element film 20 or the second memory element film 30 in the first embodiment is an oxide of one kind of metal.

The second memory element film 30 contains an oxide of the metal element contained in the first memory element film 20. The second memory element film 30 is provided in part of the lower side of the upper electrode film 11 or the entire region of the lower side of the upper electrode film 11.

The absolute value of the standard Gibbs free energy of formation ΔG (kJ/mol, 298.15 K) per one oxygen atom when the lower electrode film 10 or the upper electrode film 11 changes into an oxide film is smaller than the absolute value of the standard Gibbs free energy of formation per one oxygen atom of the oxide contained in the first memory element film 20.

The absolute value of the standard Gibbs free energy of formation per one oxygen atom of the oxide contained in the second memory element film 30 is larger than the absolute value of the standard Gibbs free energy of formation per one oxygen atom when the upper electrode film 11 changes into an oxide film.

The concentration (mol/cm³) of oxygen contained in the second memory element film 30 is higher than the concentration of oxygen contained in the first memory element film 20. The resistance between the lower electrode film 10 and the upper electrode film 11 in the second state shown in FIG. 1B is higher than the resistance between the lower electrode film 10 and the upper electrode film 11 in the first state shown in FIG. 1A.

The operation of the memory cell 100 will now be described.

It is possible to perform the writing and reading of information on the memory cell 100 without forming a filament that forms a current path between the lower electrode film 10 and the upper electrode film 11.

For example, in the first state (the set state) shown in FIG. 1A, the resistance between the lower electrode film 10 and the upper electrode film 11 of the memory cell 100 is in a low resistive state. This is because, in the set state, the condition is in a state where the first memory element film 20 including an oxygen-deficient metal oxide film (a metal-rich metal oxide film) is placed between the lower electrode film 10 and the upper electrode film 11. The oxygen-deficient metal oxide film is not a complete insulator but allows a current with a prescribed current value to flow between the lower electrode film 10 and the upper electrode film 11.

In the second state (the reset state) shown in FIG. 1B, the resistance between the lower electrode film 10 and the upper electrode film 11 of the memory cell 100 is in a high resistive state. This is because, in the reset state, the second memory element film 30 formed by anode oxidation exists between the upper electrode film 11 and the first memory element film 20. The second memory element film 30 includes a metal oxide film having a higher oxygen concentration than the first memory element film 20.

The memory cell 100 is prepared beforehand in the first state (the set state) (see FIG. 1A). In the first state, the first memory element film 20 includes a metal oxide film with a low oxygen concentration. In the first state, electrons move in the first memory element film 20 via traps resulting from oxygen deficiency. Thereby, in the first state, the resistance between the lower electrode film 10 and the upper electrode film 11 is low.

When the upper electrode film 11 is made the anode, the lower electrode film 10 is made the cathode, and a voltage is applied between the lower electrode film 10 and the upper electrode film 11, negative oxygen ions move to the vicinity of the upper electrode film 11 side that is the anode due to the electric field (see FIG. 1B). As a mechanism of the movement of oxygen ions, there is a movement due to the electric field of ions and a movement by electromigration due to collisions with electrons. When the portion between the electrode films is a high resistance, the movement therein is preferentially the movement due to the electric field, and this is suitable for an element that requires low power consumption. On the other hand, when the portion between the electrode films is a low resistance, the movement therein is preferentially the movement by electromigration, and this is suitable for an element that requires high-speed operation although the power consumption is large. An appropriate system may be employed in accordance with the requirements of the elements. Furthermore, since a current flows between the lower electrode film 10 and the upper electrode film 11, Joule heat is generated in the first memory element film 20. Due to the Joule heat, the oxygen ions that have moved to the vicinity of the upper electrode film 11 side promote the oxidation of the first memory element film 20 in the vicinity of the upper electrode film 11 side.

After that, the electrons of the oxygen ions are released to the upper electrode film 11, and the second memory element film 30 with a uniform thickness in which oxidation has more proceeded than in the first memory element film 20 is formed near the anode. The second memory element film 30 has a composition ratio equal or near to a stoichiometric ratio as compared to the first memory element film 20. The concentration of oxygen contained in the second memory element film 30 is higher than the concentration of oxygen contained in the first memory element film 20. At the time after the second memory element film 30 with a higher oxygen concentration is formed, the oxygen concentration of the first memory element film 20 is lower than that in the state shown in FIG. 1A because oxygen in the first memory element film 20 has moved into the second memory element film 30.

Therefore, the insulating properties of the second memory element film 30 are higher than the insulating properties of the first memory element film 20. Thereby, the resistance between the lower electrode film 10 and the upper electrode film 11 transitions from a low resistance to a high resistance. That is, the memory cell 100 transitions from the first state that is a low resistance state to the second state that is a high resistance state.

In the second state, the film thickness of the second memory element film 30 is controlled by the voltage applied between the lower electrode film 10 and the upper electrode film 11 or the current value of the portion between the lower electrode film 10 and the upper electrode film 11. To increase the film thickness of the second memory element film 30 more, the voltage or the current is more increased.

However, if the voltage is excessively increased, the second memory element film 30 itself is broken by the voltage. Therefore, the voltage applied between the lower electrode film 10 and the upper electrode film 11 may be appropriately adjusted to control the thickness of the second memory element film 30 to, for example, 3 nm (nanometers) or less.

Furthermore, after the memory cell 100 has transitioned into the second state, by making the lower electrode film 10 the anode and the upper electrode film 11 the cathode, oxygen in the metal oxide film on the upper electrode film 11 side moves in the opposite direction, that is, away from the interface between the upper electrode film 11 and the first memory element film 20, and moves from the upper electrode film 11 side to the lower electrode film 10 side (see FIG. 1A). That is, the metal oxide film formed by anode oxidation disappears, and the condition changes from the second state that is the high resistance state back to the first state that is the low resistance state. When the condition changes from the second state back to the first state, the electric field is concentrated in the second memory element film 30 that is a higher resistance. Therefore, oxygen ions in the second memory element film 30 move into the first memory element film 20 due to the concentrated electric field. When oxygen ions in the second memory element film 30 have moved into the first memory element film 20, the second memory element film 30 disappears and the first memory element film 20 is formed between the upper electrode film 11 and the lower electrode film 10. The oxygen concentration of the first memory element film 20 in this stage is the same as that in the state shown in FIG. 1A.

Thus, in the memory cell 100, the second memory element film 30 is produced and eliminated, and the low resistance state and the high resistance state are repeated. Thereby, data can be written to and erased from the memory cell 100.

Here, the relationship is described between the absolute value of the standard Gibbs free energy of formation ΔG per one oxygen atom when the upper electrode film 11 changes into an oxide film and the absolute value of the standard Gibbs free energy of formation ΔG per one oxygen atom of the oxide contained in the first memory element film 20.

For example, it is assumed that an oxide of manganese (Mn) is used as the material of the first memory element film 20 or the material of the second memory element film 30. The second memory element film 30 is more oxidized than the first memory element film 20. That is, the ratio of manganese to oxygen (Mn/O) is smaller in the second memory element film 30. Further, it is assumed that nickel (Ni) is used as the material of the upper electrode film 11.

The following formula shows a reaction between manganese oxide and nickel in which nickel takes oxygen away from manganese oxide and the nickel itself becomes an oxide.

(¼)Mn₃O₄+Ni−>(¾)Mn+NiO

The ΔG of the left-hand side is ΔG=(¼)×(−1435 (kJ/mol, 298.15 K))=−359 (kJ/mol, 298.15 K), and the ΔG of the right-hand side is ΔG=−211 (kJ/mol, 298.15 K).

That is, the ΔG of the left-hand side is smaller than the ΔG of the right-hand side. Therefore, it is difficult for the reaction expressed by the above formula to progress to the right-hand side. The result shows that a metal having a smaller standard Gibbs free energy of formation per one oxygen atom of the oxide is a metal more likely to take away oxygen.

In the memory cell 100, the oxygen-deficient first memory element film 20 is anode-oxidized to form the second memory element film 30 near the anode. Thereby, the memory cell 100 transitions from the low resistance state to the high resistance state. However, if the anode is made of a material more likely to take away oxygen than the metal material contained in the first memory element film 20 or the second memory element film 30, the anode itself is undesirably oxidized in the operation of the memory cell 100.

Therefore, the following relationship holds between the upper electrode film 11 that forms the anode and the first memory element film 20 or the second memory element film 30.

(the absolute value of the standard Gibbs free energy of formation per one oxygen atom of the oxide contained in the first memory element film 20 or the second memory element film 30)>(the absolute value of the standard Gibbs free energy of formation per one oxygen atom when the upper electrode film 11 changes into an oxide film)

In order that also the lower electrode film 10 itself may not be oxidized in the operation of the memory cell 100, the design may be made so that the absolute value of the standard Gibbs free energy of formation per one oxygen atom when the lower electrode film 10 changes into an oxide film may be smaller than the absolute value of the standard Gibbs free energy of formation per one oxygen atom of the oxide contained in the first memory element film 20. For example, the material of the lower electrode film 10 may be the same as the material of the upper electrode film 11.

FIG. 2 is a graph showing the absolute value of the standard Gibbs free energy of formation per one oxygen atom of each of a plurality of metal oxides.

The horizontal axis of FIG. 2 shows each of a plurality of metal oxides, and the vertical axis represents the absolute value of the standard Gibbs free energy of formation per one oxygen atom of each of the plurality of metal oxides. An oxide having a larger absolute value of the vertical axis means a more stable oxide. Specific examples of the metal are shown in the graph of FIG. 2, and specific examples of the oxide is shown at the horizontal axis of FIG. 2.

For example, in the case where the upper electrode film 11 is made of ruthenium (Ru), in order that the relationship described above may hold, an oxide of a metal selected from the group consisting of copper (Cu), rhenium (Re), nickel (Ni), cobalt (Co), molybdenum (Mo), tungsten (W), chromium (Cr), niobium (Nb), manganese (Mn), tantalum (Ta), and the like may be selected as the material of the first memory element film 20 or the material of the second memory element film 30.

In the case where the upper electrode film 11 is made of tantalum (Ta), in order that the relationship described above may hold, an oxide of an element selected from the group consisting of vanadium (V), silicon (Si), titanium (Ti), zirconium (Zr), aluminum (Al), hafnium (Hf), and the like may be selected as the material of the first memory element film 20 or the material of the second memory element film 30.

Thus, in the first embodiment, information is written to and read from the memory cell 100 without forming a filament. The first embodiment does not depend on a stochastic method in which part of the first memory element film 20 or part of the second memory element film 30 is broken. Therefore, in the first embodiment, there is no case where the breakdown voltage of the metal oxide film varies or the level of filament formation varies between memory cells like examples in which a filament is formed.

Furthermore, since the thickness of the second memory element film 30 is controlled to, for example, approximately 3 nm or less, the memory cell does not undergo dielectric breakdown, and the power consumption of the memory cell 100 does not significantly increase. In addition, when forming the second memory element film 30, it is not necessary to raise the voltage gradually to a voltage that causes voltage breakdown like examples in which a filament is formed. Consequently, a large amount of manufacturing time is not required. Therefore, nonvolatile memory devices including the memory cell 100 can be manufactured at low cost and are excellent also in productivity.

### Second Embodiment

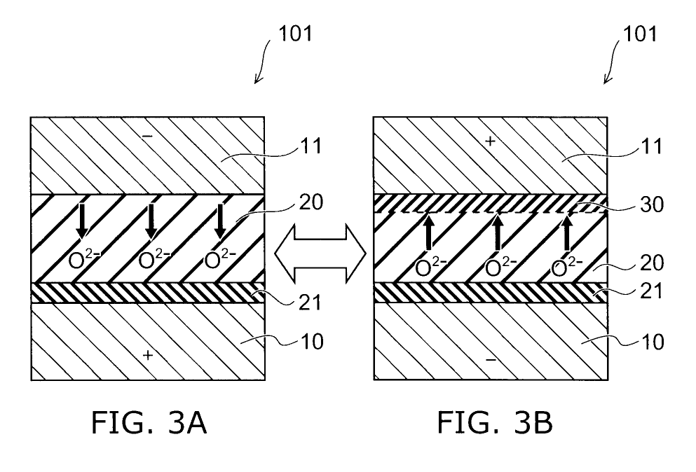

FIGS. 3A and 3B are schematic cross-sectional views of a memory cell of a nonvolatile memory device according to a second embodiment.

FIGS. 3A and 3B show the first state (FIG. 3A) and the second state (FIG. 3B) similarly to FIGS. 1A and 1B. FIG. 3A shows the state after setting, and FIG. 3B shows the state after resetting.

A memory cell 101 of a nonvolatile memory device according to the second embodiment further includes an electric field control film 21 containing an oxide (a third oxide) between the lower electrode film 10 and the first memory element film 20. The electric field control film 21 has a film thickness of 10 nm or less.

The dielectric constant of the first memory element film 20 is higher than the dielectric constant of the electric field control film 21. As an example, the first memory element film 20 is a high-k material, and the electric field control film 21 is a low-k material. The band gap of the electric field control film 21 is wider than the band gap of the first memory element film 20.

The absolute value of the standard Gibbs free energy of formation per one oxygen atom of the oxide contained in the first memory element film 20 is smaller than the absolute value of the standard Gibbs free energy of formation per one oxygen atom of the oxide contained in the electric field control film 21.

The absolute value of the standard Gibbs free energy of formation per one oxygen atom of the oxide contained in the electric field control film 21 is larger than the absolute value of the standard Gibbs free energy of formation per one oxygen atom when the lower electrode film 10 changes into an oxide film. The electric field control film 21 preferably has a composition of a stoichiometric ratio in order not to take oxygen away from the first memory element film 20. For example, in the case where the oxygen concentration of a metal oxide having a stoichiometric ratio is taken as a standard, the electric field control film 21 is a metal oxide having an oxygen concentration in a range of ±10% of the above oxygen concentration.

By providing the electric field control film 21 in the memory cell 101, the memory cell 101 exhibits rectifying properties.

Before describing the operation of the memory cell 101, an example of the operation of the memory cell 100 in which the electric field control film 21 is not provided is described.

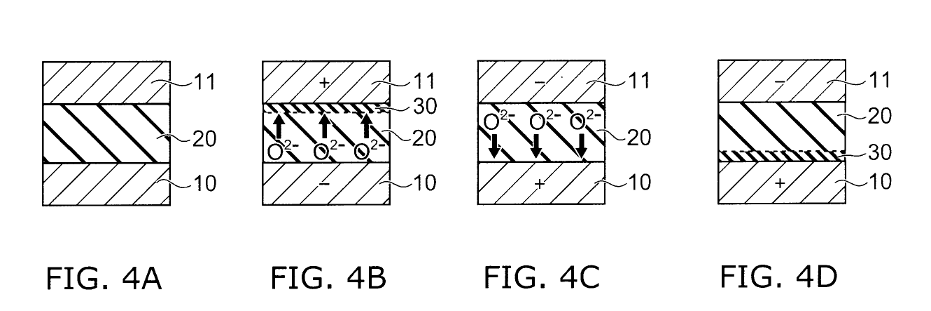

FIGS. 4A to 4D are schematic cross-sectional views for describing an example of the operation of a memory cell in which the electric field control film is not provided.

In the memory cell 100, it is assumed that the material of the lower electrode film 10 and the material of the upper electrode film 11 are the same.

For example, the state of FIG. 4A is the first state (the set state) described above. The state of FIG. 4B is the second state (the reset state) described above. After the memory cell 100 has transitioned from the first state to the second state, by making the lower electrode film 10 the anode and the upper electrode film 11 the cathode, oxygen in the metal oxide film on the upper electrode film 11 side moves in the opposite direction, that is, away from the interface between the upper electrode film 11 and the first memory element film 20, and moves from the upper electrode film 11 side to the lower electrode film 10 side. That is, the metal oxide film formed by anode oxidation disappears, and the condition changes from the second state that is the high resistance state back to a third state that is the low resistance state. The third state is the same as the first state.

However, in the case where the material of the lower electrode film 10 and the material of the upper electrode film 11 are the same, excessive continuation of the third state may form the second memory element film 30 also on the lower electrode film 10 side as shown in FIG. 4D. That is, FIG. 4D is undesirably the same as the structure in which the stacked film structure of FIG. 4B is reversed by 180 degrees. Therefore, a malfunction may be caused in writing and reading in the memory cell 100.

Next, the operation of the memory cell 101 according to the second embodiment is described.

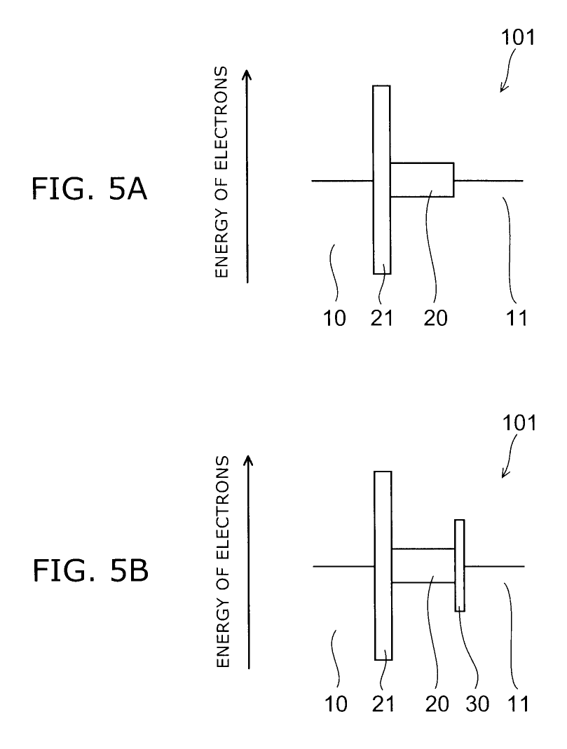

FIGS. 5A and 5B are schematic diagrams of the energy band structure of the memory cell according to the second embodiment.

FIG. 5A shows the energy band of the first state, and FIG. 5B shows the energy band of the second state.

In FIG. 5A, the energy bands of the lower electrode film 10, the electric field control film 21, the first memory element film 20, and the upper electrode film 11 are shown in this order from the left side to the right side.

In FIG. 5B, the energy bands of the lower electrode film 10, the electric field control film 21, the first memory element film 20, the second memory element film 30, and the upper electrode film 11 are shown in this order from the left side to the right side.

As described above, the band gap of the electric field control film 21 is wider than the band gap of the first memory element film 20. The dielectric constant of the electric field control film 21 is lower than the dielectric constant of the first memory element film 20.

The absolute value of the standard Gibbs free energy of formation per one oxygen atom of the oxide contained in the electric field control film 21 is larger than the absolute value of the standard Gibbs free energy of formation per one oxygen atom of the oxide contained in the first memory element film 20.

The absolute value of the standard Gibbs free energy of formation per one oxygen atom of the oxide contained in the electric field control film 21 is larger than the absolute value of the standard Gibbs free energy of formation per one oxygen atom when the lower electrode film 10 changes into an oxide film.

The absolute value of the standard Gibbs free energy of formation per one oxygen atom of the oxide contained in the first memory element film 20 is larger than the absolute value of the standard Gibbs free energy of formation per one oxygen atom when the upper electrode film 11 changes into an oxide film.

The absolute value of the standard Gibbs free energy of formation per one oxygen atom of the oxide contained in the second memory element film 30 is larger than the absolute value of the standard Gibbs free energy of formation per one oxygen atom when the upper electrode film 11 changes into an oxide film.

In the memory cell 101, the voltage applied between the lower electrode film 10 and the upper electrode film 11 is divided in accordance with the ratio of the dielectric constants of the oxides between the lower electrode film 10 and the upper electrode film 11. The lower the dielectric constant of an oxide is, the higher the divided voltage applied to the oxide is. Therefore, if it is assumed that the film thickness of the first memory element film 20 and the film thickness of the electric field control film 21 are the same, a higher voltage is applied to the electric field control film 21 than to the first memory element film 20.

Furthermore, in the second embodiment, the film thickness of the electric field control film 21 is adjusted to a level allowing a tunnel current to flow through the electric field control film 21. Specifically, the film thickness of the electric field control film 21 is set not more than 10 nm. If the film thickness of the electric field control film 21 is 10 nm or more, a tunnel current flows less easily, and this is not preferable.

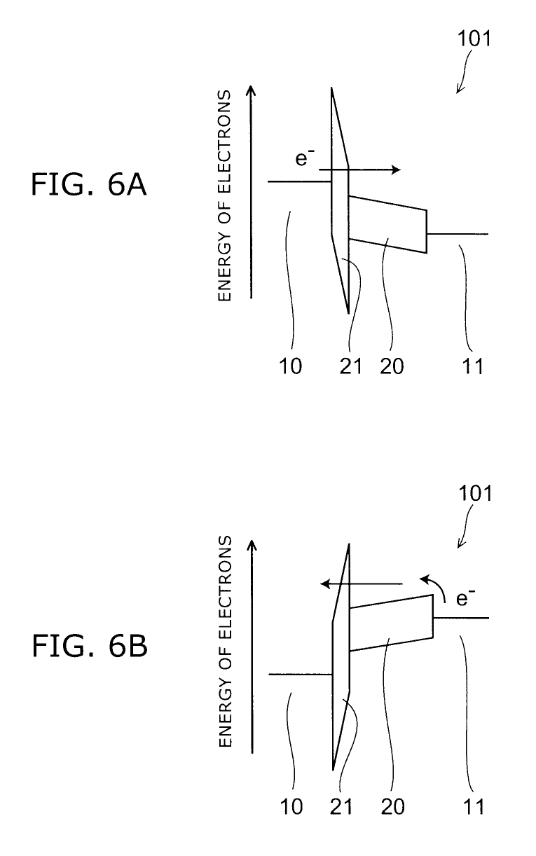

FIGS. 6A and 6B are schematic diagrams of the energy band structure in the operation of the memory cell according to the second embodiment.

As shown in FIG. 6A, in the case where the lower electrode film 10 is negative and the upper electrode film 11 is positive, electrons supplied from the lower electrode film 10 tunnel through the electric field control film 21 to reach the upper electrode film 11 without being affected by the potential barrier of the first memory element film 20. That is, in the state of FIG. 6A, electrons pass from the lower electrode film 10 to the upper electrode film 11 only by tunneling.

However, as shown in FIG. 6B, in the case where the lower electrode film 10 is positive and the upper electrode film 11 is negative, electrons supplied from the upper electrode film 11 need to surmount the potential barrier of the first memory element film 20 and tunnel through the electric field control film 21 to reach the lower electrode film 10. That is, in the state of FIG. 6B, electronic excitation for surmounting the potential barrier of the first memory element film 20 is necessary. Therefore, the state of FIG. 6B has a higher resistance than the state of FIG. 6A. Thus, rectifying properties are produced in the memory cell 101.

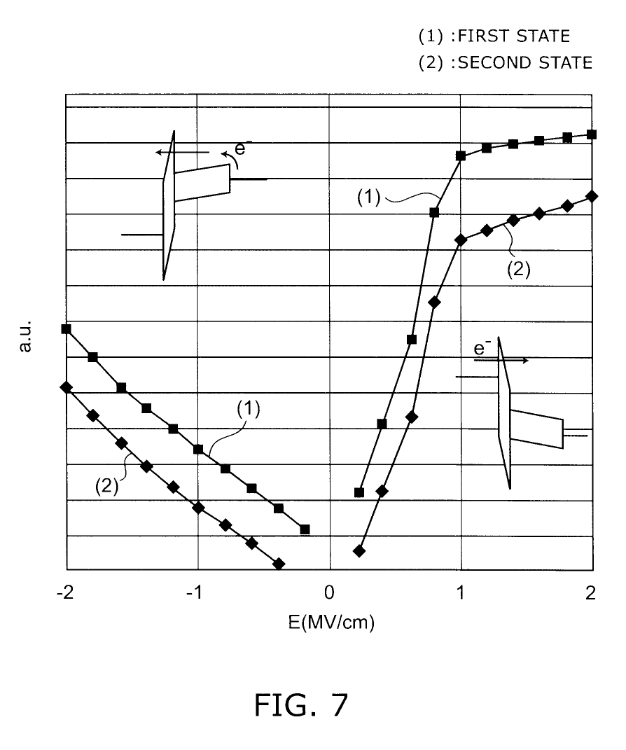

FIG. 7 is the simulation results of the current-voltage characteristics of the memory cell.

In the horizontal axis of FIG. 7, the right side of the center 0 (MV/cm) of the horizontal axis corresponds to the state of FIG. 6A, and the left side corresponds to the state of FIG. 6B. The vertical axis is the current value of the memory cell (the unit being a.u.; arbitrary unit). FIG. 7 shows the results of the current-voltage curve of the first state (1) in the case where the second memory element film 30 is not present and the current-voltage curve of the second state (2) in the case where the second memory element film 30 is present.

In the simulation, the specific example described below is used.

For example, the electric field control film 21 is made of silicon oxide (SiO₂), and has an energy gap (Eg) of 9.65 (eV), a dielectric constant (∈) of 4.0, and a film thickness of 5 nm.

The first memory element film 20 is made of oxygen-deficient tantalum oxide (TaOₓ), and has an energy gap (Eg) of 1.0 (eV), a dielectric constant (∈) of 21, and a film thickness of 13 nm in the first state and 15 nm in the second state.

The second memory element film 30 is made of tantalum oxide having a stoichiometric ratio (Ta₂O₅), and has an energy gap (Eg) of 4.6 (eV), a dielectric constant (∈) of 21, and a film thickness of 2 nm.

The work function of the lower electrode film 10 and the upper electrode film 11 is assumed to be the middle point of those of the electric field control film 21, the first memory element film 20, and the second memory element film 30. The height from the Fermi level (Ef) of the lower electrode film 10 and the upper electrode film 11 to the conduction band of each of the electric field control film 21, the first memory element film 20, and the second memory element film 30 is assumed to be half of the respective Eg.

As shown in FIG. 7, it has been found that the current value is higher by three or more figures in the case where the upper electrode film 11 is set positive and the lower electrode film 10 is set negative (the right side of the graph) than in the case where the upper electrode film 11 is set negative and the lower electrode film 10 is set positive (the left side of the graph), regardless of the first state (1) and the second state (2). Thus, the memory cell 101 exhibits rectifying properties. Therefore, such a malfunction in writing and reading as is described above is suppressed to provide higher reliability.

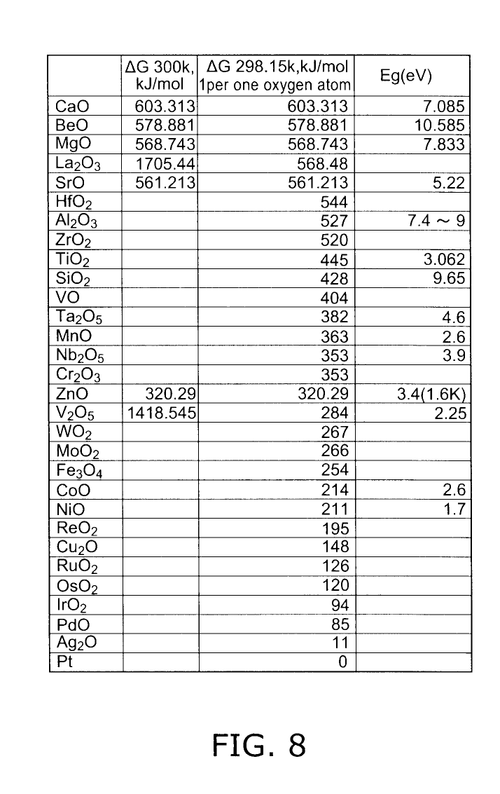

FIG. 8 is a list of the absolute value of the standard Gibbs free energy of formation, the absolute value of the standard Gibbs free energy of formation per one oxygen atom, and the energy gap of each of a plurality of metal oxides.

In view of the absolute value of the standard Gibbs free energy of formation, the absolute value of the standard Gibbs free energy of formation per one oxygen atom, and the energy gap of each of the metal oxides illustrated in FIG. 8, the specific materials of the lower electrode film 10, the electric field control film 21, the first memory element film 20, the second memory element film 30, and the upper electrode film 11 of the memory cell 101 are, for example, as follows.

As the first memory element film 20, for example, Nb₂O₅, Ta₂O₅, Cr₂O₃, V₂O₅, or the like is given. However, the oxide of the first memory element film 20 is not limited to the stoichiometric ratios of the chemical formulae described above, but may be an oxygen-deficient oxide.

As the second memory element film 30, for example, Nb₂O₅, Ta₂O₅, Cr₂O₃, V₂O₅, or the like is given.

As the electric field control film 21, CaO, BeO, MgO, La₂O₃, HfO₂, ZrO₂, Al₂O₃, SiO₂, or the like is given.

As the upper electrode film 11, for example, platinum (Pt), silver (Ag), Ru, palladium (Pd), iridium (Ir), osmium (Os), Re, Ni, Co, iron (Fe), Mo, W, V, zinc (Zn), or the like is given.

As the lower electrode film 10, for example, Pt, Ag, Ru, Pd, Ir, Os, Re, Ni, Co, Fe, Mo, W, V, Zn, Cr, Nb, Ta, titanium (Ti), titanium nitride (TiN), niobium nitride (NbN), tantalum nitride (TaN), or the like is given.

### Third Embodiment

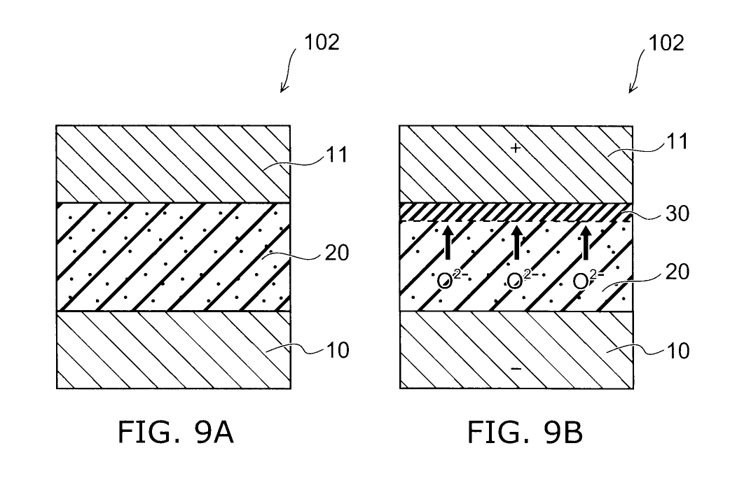

FIGS. 9A and 9B are schematic cross-sectional views of a memory cell of a nonvolatile memory device according to a third embodiment.

FIGS. 9A and 9B show the first state (FIG. 9A) and the second state (FIG. 9B) similarly to FIGS. 1A and 1B. FIG. 9A shows the state after setting, and FIG. 9B shows the state after resetting.

In a memory cell 102 according to the third embodiment, the first memory element film 20 shown in FIG. 9A is formed of an oxide film of two or more metal elements. In this case, the second memory element film 30 shown in FIG. 9B is formed of an oxide film of the metal element having the largest absolute value of the standard Gibbs free energy of formation per one oxygen atom out of the two or more metal elements mentioned above.

In the first embodiment, the first memory element film 20 is an oxide of one kind of metal, whereas in the third embodiment, the first memory element film 20 is a metal oxide film containing two or more kinds of metals. An example thereof is that the first memory element film 20 is TiOₓ doped with Nb (NTO) and the second memory element film 30 is TiO₂.

In the case where the first memory element film 20 is formed of an oxide film of at least two metals of Ti, Ta, Nb, W, Fe, and Cu, the second memory element film 30 is TiO₂, Ta₂O₅, Nb₂O₅, or the like, which have a relatively large absolute value of the standard Gibbs free energy of formation per one oxygen atom.

Thus, in the memory cell 102, the first memory element film 20 has a configuration in which a metal oxide film formed of a certain metal element is mixed with one or more other kinds of metal elements in order to obtain the low resistance state shown in FIG. 9A. An oxide of the most easily oxidizable metal (the oxide with the largest AG) out of the metal elements contained in the first memory element film 20 forms the second memory element film 30 shown in FIG. 9B.

Also the memory cell 102 thus configured can maintain the first state of the low resistance state and the second state of the high resistance state.

### Fourth Embodiment

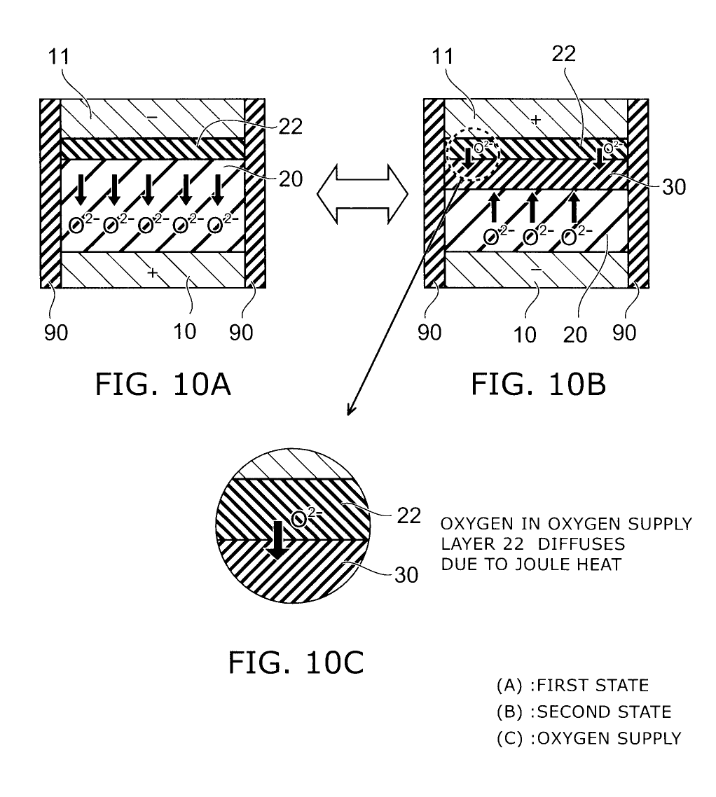

FIGS. 10A to 10C are schematic cross-sectional views of a memory cell of a nonvolatile memory device according to a fourth embodiment.

FIGS. 10A to 10C show the first state (FIG. 10A) and the second state (FIG. 10B) similarly to FIGS. 1A and 1B. FIG. 10C is an enlarged view of part of FIG. 10B. FIG. 10A shows the state after setting, and FIG. 10B shows the state after resetting.

A memory cell 103 according to the fourth embodiment further includes an oxygen supply layer 22 containing a conductive oxide between the upper electrode film 11 and the first memory element film 20 or between the upper electrode film 11 and the second memory element film 30. The oxygen supply layer 22 has a resistivity of 100 (μΩ·cm) or less at room temperature. For the memory cell 103, a side wall 90 is provided on both sides of the cell. The side wall 90 covers the side surfaces of the first memory element film 20, the second memory element film 30, and the oxygen supply layer 22.

The absolute value of the standard Gibbs free energy of formation per one oxygen atom of the conductive oxide contained in the oxygen supply layer 22 is smaller than the absolute value of the standard Gibbs free energy of formation per one oxygen atom of the oxide contained in the first memory element film 20.

The operation of the memory cell 103 will now be described.

In the memory cell 103, also when the oxygen concentration of the first memory element film 20 is decreased, oxygen is supplied from the oxygen supply layer 22 into the first memory element film 20. Thereby, the oxygen concentration of the first memory element film 20 is kept constant.

The oxygen supply layer 22 containing a conductive oxide has a smaller resistivity than the first memory element film 20. Therefore, at the time of resetting in which the memory cell 103 is changed from the first state of FIG. 10A to the second state of FIG. 10B, most of the voltage applied between the lower electrode film 10 and the upper electrode film 11 drops at the first memory element film 20. Therefore, little electric field is generated in the oxygen supply layer 22. Furthermore, in the first memory element film 20 in contact with the oxygen supply layer 22, Joule heat is generated due to the current flowing between the lower electrode film 10 and the upper electrode film 11.

The Joule heat is conducted also into the oxygen supply layer 22. Thereby, the thermal diffusion of the oxygen in the oxygen supply layer 22 is promoted (see FIG. 10C). Furthermore, due to the Coulomb force, oxygen ions in the first memory element film 20 move toward the upper electrode film 11 side. Thereby, the oxygen ions that have moved toward the upper electrode film 11 promote the oxidation of the anode side of the first memory element film 20, and the second memory element film 30 is formed.

Furthermore, the absolute value of the standard Gibbs free energy of formation per one oxygen atom of the conductive oxide contained in the oxygen supply layer 22 is smaller than the absolute value of the standard Gibbs free energy of formation per one oxygen atom of the oxide contained in the first memory element film 20. Therefore, the oxygen thermally diffused in the first memory element film 20 is less likely to be attracted to and reduced in the oxygen supply layer 22. Thus, in the memory cell 103, the oxygen concentration of the first memory element film 20 can be kept constant.

Moreover, after the memory cell 103 has transitioned into the second state, by making the lower electrode film 10 the anode and the upper electrode film 11 the cathode, oxygen in the second memory element film 30 on the upper electrode film 11 side moves to the first memory element film 20. That is, the second memory element film 30 formed by anode oxidation disappears, and the condition changes from the second state that is the high resistance state back to the first state that is the low resistance state.

As the oxide contained in the first memory element film 20, in addition to the materials described above, an oxide of one of Ti, Si, V, Ta, Mn, Nb, Cr, W, Mo, Fe, Co, Ni, Re, Cu, Ru, Os, Ir, Pd, Ag, and the like, for example, is selected.

In the case where these oxides are selected as the first memory element film 20, one that is in a condition satisfying the magnitude relationship of the standard Gibbs free energy of formation described above out of the oxides of one of Mo, Re, Ru, Os, Ir, and the like may be selected as the oxygen supply layer 22. In the case where a multicomponent material containing a plurality of metal elements and/or semiconductor elements is selected as the first memory element film 20, it is sufficient that one element of them be in a condition satisfying the magnitude relationship of the standard Gibbs free energy of formation described above.

For example, a combination in which the first memory element film 20 is NbOₓ (x<2.5) and the oxygen supply layer 22 is RuOₓ (x<2) is given as a combination of the first memory element film 20 and the oxygen supply layer 22. Alternatively, a combination in which the first memory element film 20 is TaOₓ (x<2.5) and the oxygen supply layer 22 is RuOₓ (x<2) is given as another combination.

If the oxygen supply layer 22 is not provided, in the operation of the memory cell, the oxygen concentration in the first memory element film 20 may decrease to cause a defective formation of the second memory element film 30.

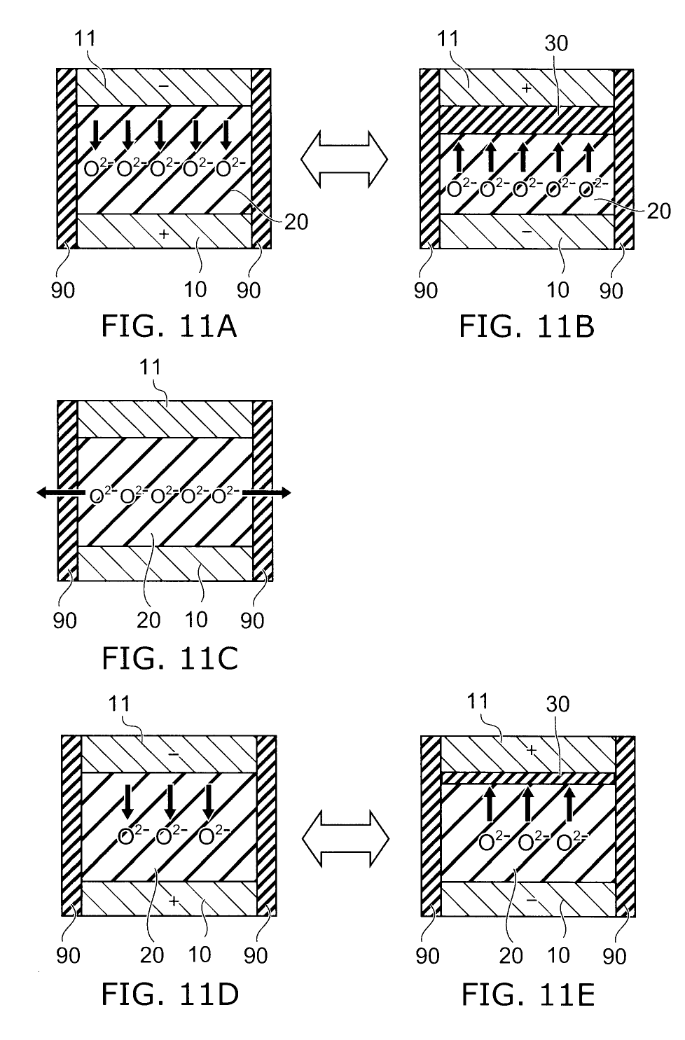

FIGS. 11A to 11E are schematic cross-sectional views for describing a defective formation of the second memory element film.

Here, FIG. 11A is a view showing the first state at a normal oxygen concentration, FIG. 11B is a view showing the second state at a normal oxygen concentration, FIG. 11C is a view showing a decrease in the oxygen concentration, FIG. 11D is a view showing the first state at a low oxygen concentration, and FIG. 11E is a view showing the second state at a low oxygen concentration.

If the oxygen supply layer 22 is not provided, as shown in FIG. 11C, oxygen in the first memory element film 20 may diffuse to the outside of the memory cell to decrease the oxygen concentration in the first memory element film 20 in the operation of the memory cell. Furthermore, the oxygen concentration of the first memory element film 20 may decrease also in element fabrication processes, such as during cell processing by RIE (reactive ion etching) where oxygen of the first memory element film 20 may come out due to the collisions of ions with the first memory element film 20.

If the first state shown in FIG. 11A and the second state shown in FIG. 11B are repeated in such a state, since the oxygen concentration in the first memory element film 20 is not enough, the second memory element film 30 that is a high resistance layer may not be formed on the entire lower surface of the upper electrode film 11, or the film thickness of the second memory element film 30 may be decreased. Thereby, the resistance value in the high resistance state (Roff) is decreased.

FIG. 11D shows the first state at a low oxygen concentration. FIG. 11E shows the second state at a low oxygen concentration. The second memory element film 30 formed at a low oxygen concentration has a thinner film thickness than the second memory element film 30 formed at a normal oxygen concentration. This may cause a malfunction in which the resistance value in the high resistance state (Roff) and the resistance value in the low resistance state (Ron) cannot be sufficiently distinguished.

By the fourth embodiment, a resistance value decrease in the second state is suppressed, and the operation of the memory cell 103 is more stabilized. Furthermore, by the fourth embodiment, oxygen deficiency (what is called oxygen detachment) is suppressed not only in the operation of the memory cell 103 but also in the manufacturing processes of the memory cell 103. For example, oxygen detachment due to ion bombardment in RIE processing etc. can be prevented.

### Fifth Embodiment

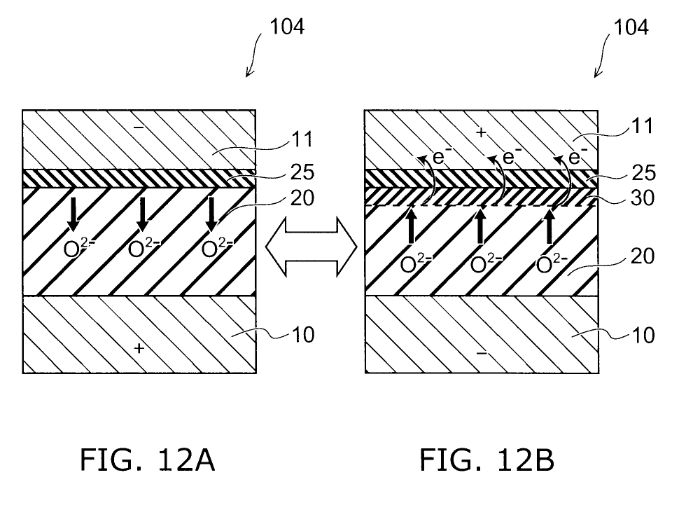

FIGS. 12A and 12B are schematic cross-sectional views of a memory cell of a nonvolatile memory device according to a fifth embodiment.

FIGS. 12A and 12B show the first state (FIG. 12A) and the second state (FIG. 12B) similarly to FIGS. 1A and 1B. FIG. 12A shows the state after setting, and FIG. 12B shows the state after resetting.

A memory cell 104 according to the fifth embodiment includes an insulating layer 25 containing an oxide (a fourth oxide) between the upper electrode film 11 and the first memory element film 20 or between the upper electrode film 11 and the second memory element film 30. The insulating layer 25 has a thickness of not less than 0.5 nm and not more than 2.0 nm. The chemical composition of the oxide contained in the insulating layer 25 is near to a stoichiometric ratio as compared to the chemical composition of the oxide contained in the first memory element film 20. The resistivity of the insulating layer 25 is higher than the resistivity of the first memory element film 20 or the resistivity of the second memory element film 30.

The absolute value of the standard Gibbs free energy of formation per one oxygen atom of the oxide contained in the insulating layer 25 is larger than the absolute value of the standard Gibbs free energy of formation per one oxygen atom of the oxide contained in the first memory element film 20.

The absolute value of the standard Gibbs free energy of formation per one oxygen atom of the oxide contained in the insulating layer 25 is larger than the absolute value of the standard Gibbs free energy of formation per one oxygen atom when the upper electrode film 11 changes into an oxide film.

The band gap of the insulating layer 25 is wider than the band gap of the first memory element film 20 and narrower than the band gap of the electric field control film 21.

The first memory element film 20 and the insulating layer 25 contain an oxide of a transition element or the like. The absolute value of the standard Gibbs free energy of formation per one oxygen atom of the oxide contained in the insulating layer 25 is adjusted to a value larger than the absolute value of the standard Gibbs free energy of formation per one oxygen atom of the oxide contained in the first memory element film 20. That is, a material less likely to reduce oxygen from the insulating layer 25 is selected as the first memory element film 20.

In the memory cell 104, the composition of the oxide contained in the insulating layer 25 is adjusted to a stoichiometric composition (a stoichiometric ratio) so that the insulating layer 25 may not reduce the first memory element film 20. The film thickness of the insulating layer 25 is adjusted to a level allowing a tunneling current to flow. For example, the film thickness of the insulating layer 25 is within a range of not less than 0.5 nm and not more than 2.0 nm. If the insulating layer 25 has a film thickness thinner than 0.5 nm, the insulating layer 25 itself loses insulating properties, and this is not preferable. If the insulating layer 25 has a film thickness thicker than 2.0 nm, a tunneling current flows less easily, and this is not preferable.

The absolute value of the standard Gibbs free energy of formation per one oxygen atom of the oxide contained in the insulating layer 25 is larger than the absolute value of the standard Gibbs free energy of formation per one oxygen atom when the upper electrode film 11 changes into an oxide film. Therefore, the upper electrode film 11 is less likely to reduce oxygen of the insulating layer 25.

As the first memory element film 20, an oxide of one of Ti, Si, V, Ta, Mn, Nb, Cr, W, Mo, Fe, and the like is selected. As the insulating layer 25, an oxide of one of Hf, Al, Zr, Ti, Si, V, Ta, Mn, Nb, and the like is selected. For example, TiO₂ is selected as the insulating layer 25.

As the upper electrode film 11, Al, Ti, Si, Ta, Mn, Nb, Cr, W, Mo, Fe, Co, Ni, Re, Cu, Ru, cerium (Ce), Ir, Pd, Ag, or the like is selected. When selecting the first memory element film 20, the insulating layer 25, and the upper electrode film 11, the materials are combined so that the magnitude relationships of the standard Gibbs free energy of formation per one oxygen atom described above may be satisfied among the first memory element film 20, the insulating layer 25, and the upper electrode film 11.

Also in the case where each of the first memory element film 20, the insulating layer 25, and the upper electrode film 11 is a multicomponent material containing a plurality of metal elements and/or semiconductor elements, the materials are combined so that the magnitude relationships of the standard Gibbs free energy of formation per one oxygen atom described above may be satisfied among the first memory element film 20, the insulating layer 25, and the upper electrode film 11 in view of the standard Gibbs free energy of formation of oxides of one of the metal and/or semiconductor elements.

As an example, a combination is selected in which the first memory element film 20 is NbOₓ (x<2.5), the insulating layer 25 is Al₂O₃, and the upper electrode film 11 is TiN. As another example, a combination is selected in which the first memory element film 20 is TaOₓ (x<2.5), the insulating layer 25 is TiO₂, and the upper electrode film 11 is TiN. As still another example, a combination is selected in which the first memory element film 20 is WAlOₓ, the insulating layer 25 is TiO₂, and the upper electrode film 11 is TiN.

The operation of the memory cell 104 will now be described.

The memory cell 104 is prepared beforehand in the first state (the set state) (see FIG. 12A). In the first state, the second memory element film 30 with a different composition from the first memory element film 20 is not formed between the first memory element film 20 and the insulating layer 25. The first state is in the low resistance state.

As shown in FIG. 12B, when the lower electrode film 10 is made the cathode, the upper electrode film 11 is made the anode, and an electric field is applied between the lower electrode film 10 and the upper electrode film 11, the electric field is preferentially applied to the first memory element film 20 because the resistivity of the insulating layer 25 is higher than the resistivity of the first memory element film 20. Oxygen in the first memory element film 20 is ionized by the electric field, and oxygen ions electrically diffuse to the anode side via oxygen vacancies (lattice vacancies of oxygen) in the first memory element film 20.

Oxygen ions in the first memory element film 20 enter oxygen vacancies of the first memory element film 20 near the interface between the insulating layer 25 and the first memory element film 20, and promote the oxidation of the first memory element film 20 near the interface between the insulating layer 25 and the first memory element film 20.

In the memory cell 104, the insulating layer 25 is adjusted to have a film thickness allowing a tunneling current to flow. Therefore, the electrons of oxygen ions tunnel through the insulating layer 25 to flow to the anode. Thereby, the second memory element film 30 with a higher resistivity than the first memory element film 20 is formed between the insulating layer 25 and the first memory element film 20. The second memory element film 30 is in a state near to a stoichiometric ratio as compared to the first memory element film 20. Thus, the memory cell 104 transitions into the reset state.

Once again, the lower electrode film 10 is made the anode, the upper electrode film 11 is made the cathode, and an electric field is applied between the lower electrode film 10 and the upper electrode film 11. Since the resistivity of the insulating layer 25 is higher than the resistivity of the second memory element film 30, the electric field is preferentially applied to the second memory element film 30. As a consequence, oxygen in the second memory element film 30 is ionized, and oxygen ions electrically diffuse toward the lower electrode film 10 that is the anode. Thereby, the oxygen concentration of the second memory element film 30 is decreased, and the condition returns to the low resistance state shown in FIG. 12A.

In the memory cell 104, by performing bipolar voltage control in which the lower electrode film 10 is made the cathode or the anode, the formation and elimination of the second memory element film 30 can be repeated. Thereby, writing to and reading from the memory cell 104 are enabled. Since the resistivity of the insulating layer 25 is set lower than the resistivity of the first memory element film 20 or the resistivity of the second memory element film 30, the electric field is preferentially applied to the first memory element film 20 or the second memory element film 30 in the operation of the memory cell 104.

Furthermore, in the memory cell 104, the insulating layer 25 that has a high absolute value of the standard Gibbs free energy of formation per one oxygen atom and has a stoichiometric composition is provided between the upper electrode film 11 and the first memory element film 20. Therefore, at the time of resetting in the memory cell 104, the insulating layer 25 does not take oxygen away from the first memory element film 20. Furthermore, also at the time of setting, the insulating layer 25 does not give oxygen to the first memory element film 20. Consequently, the repeated operation of the memory cell 104 is stabilized.

Furthermore, in the memory cell 104, since the film thickness is adjusted to a level allowing a tunnel current to flow, when the upper electrode film 11 is the anode, also the insulating layer 25 functions as the anode and the second memory element film 30 is formed between the insulating layer 25 and the first memory element film 20.

Furthermore, in the memory cell 104, the material of the upper electrode film 11 is selected so as to satisfy the condition that the absolute value of the standard Gibbs free energy of formation per one oxygen atom of the oxide contained in the insulating layer 25 be larger than the absolute value of the standard Gibbs free energy of formation per one oxygen atom when the upper electrode film 11 changes into an oxide film. The material of the upper electrode film 11 needs only to be a material less likely to take oxygen away from the insulating layer 25. Therefore, materials other than Pt may be used as the material of the upper electrode film 11.

Moreover, in the memory cell 104, the film thickness of the insulating layer 25 is set thin enough to allow an electron to tunnel. Therefore, even when the insulating layer 25 is provided, rectifying properties are less likely to be produced as compared to the rectifying properties produced in the electric field control film 21. Thus, rectifying properties are less likely to be produced even if the insulating layer 25 is provided.

Here, also in the structure of the memory cell 100 shown in FIGS. 1A and 1B, the second memory element film 30 is formed without the upper electrode film 11 taking oxygen away from the first memory element film 20. Furthermore, when the condition is changed from the second state back to the first state, oxygen of the second memory element film 30 is decomposed to cause the second memory element film 30 to disappear.

However, if once the second memory element film 30 is formed, the voltage is preferentially applied to the second memory element film 30 which has a higher resistance. Thereby, in the operation of the memory cell 100, the electro-diffusion of oxygen ions may be less likely to occur in the first memory element film 20. As a result, there is a possibility that only part of the oxygen in the first memory element film 20 will contribute to the formation of the second memory element film 30 and the growth of the second memory element film 30 will reach a limit.

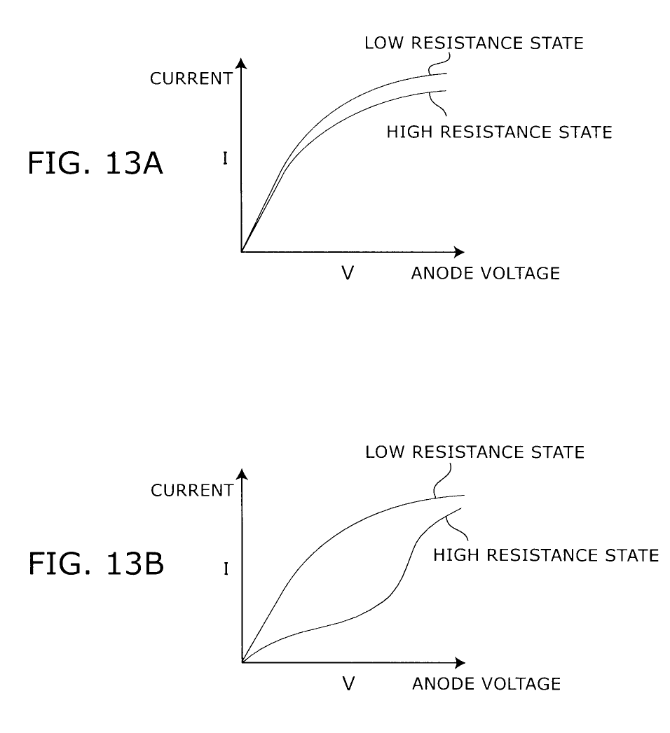

FIGS. 13A and 13B are views for describing the current-voltage characteristics of the memory cell.

FIG. 13A and FIG. 13B show examples of the current-voltage characteristics of the low resistance state that is the first state and the high resistance state that is the second state.

FIG. 13A shows an example of the current-voltage characteristics in the case where the growth of the second memory element film 30 has reached a limit. When the growth of the second memory element film 30 has reached a limit, the second memory element film 30 itself may become thin to cause a tunneling current to flow through the second memory element film 30. Therefore, as shown in FIG. 13A, a significant difference is less likely to occur in current-voltage characteristics between the low resistance state that is the first state and the high resistance state that is the second state.

In contrast, FIG. 13B shows an example of the current-voltage characteristics of the memory cell 104. In the memory cell 104, the insulating layer 25 is provided between the upper electrode film 11 and the first memory element film 20 or between the upper electrode film 11 and the second memory element film 30. Consequently, the second state has a structure in which a stacked film of the insulating layer 25/the second memory element film 30 is formed between the upper electrode film 11 and the first memory element film 20.

The thickness of the stacked film is thicker than the thickness of the second memory element film 30. Therefore, the tunneling current flowing through the stacked film is small as compared to FIG. 13A, and a significant difference occurs in current-voltage characteristics between the low resistance state that is the first state and the high resistance state that is the second state.

Furthermore, in the memory cell 104, there is little constraint on the material of the electrode, and inexpensive materials may be selected. This makes it possible to increase the capacity of the storage memory and reduce manufacturing costs.

### Sixth Embodiment

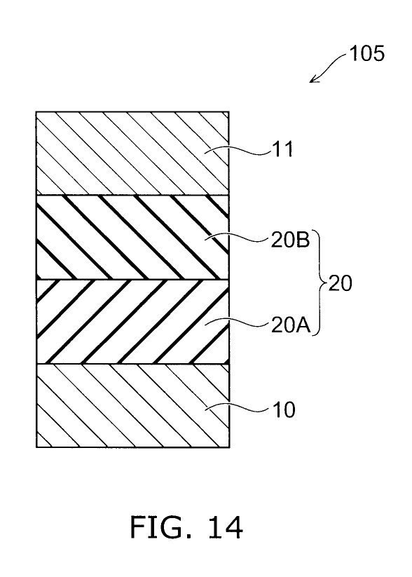

FIG. 14 is a schematic cross-sectional view of a memory cell of a nonvolatile memory device according to a sixth embodiment.

FIG. 14 shows a memory cell in the first state. The other states are described later.

In a memory cell 105 according to the sixth embodiment, the first memory element film 20 includes a first memory element unit 20A on the lower electrode film 10 side and a second memory element unit 20B on the upper electrode film 11 side. In the memory cell 105 in the first state, the first memory element unit 20A is provided on the lower electrode film 10. Furthermore, in the memory cell 105 in the first state, the second memory element unit 20B is provided on the first memory element unit 20A, and the upper electrode film 11 is provided on the second memory element unit 20B.

The absolute value of the standard Gibbs free energy of formation per one oxygen atom when the lower electrode film 10 changes into an oxide film is smaller than the absolute value of the standard Gibbs free energy of formation per one oxygen atom of the oxide contained in the first memory element unit 20A.

The absolute value of the standard Gibbs free energy of formation per one oxygen atom when the upper electrode film 11 changes into an oxide film is smaller than the absolute value of the standard Gibbs free energy of formation per one oxygen atom of the oxide contained in the second memory element unit 20B.

The metal oxides contained in the first memory element unit 20A and the second memory element unit 20B are oxygen-deficient.

The material of the lower electrode film 10 and the upper electrode film 11 is, for example, a metal selected from W, Mo, Fe, Co, Ni, Cu, Ru, Ir, and the like or an alloy of them. The material of the first memory element unit 20A and the second memory element unit 20B is an oxide containing at least one kind of metal selected from Hf, Al, Zr, Ti, Si, V, Ta, Mn, Nb, Cr, W, Mo, Co, Ni, Cu, and the like.

Thus, when the first memory element film 20 has a multiple-layer structure, the memory cell 105 can ensure a plurality of resistance value states, and multiple-valued operation (multiple-valued writing and multiple-valued reading) is possible.

The operation of the memory cell 105 will now be described.

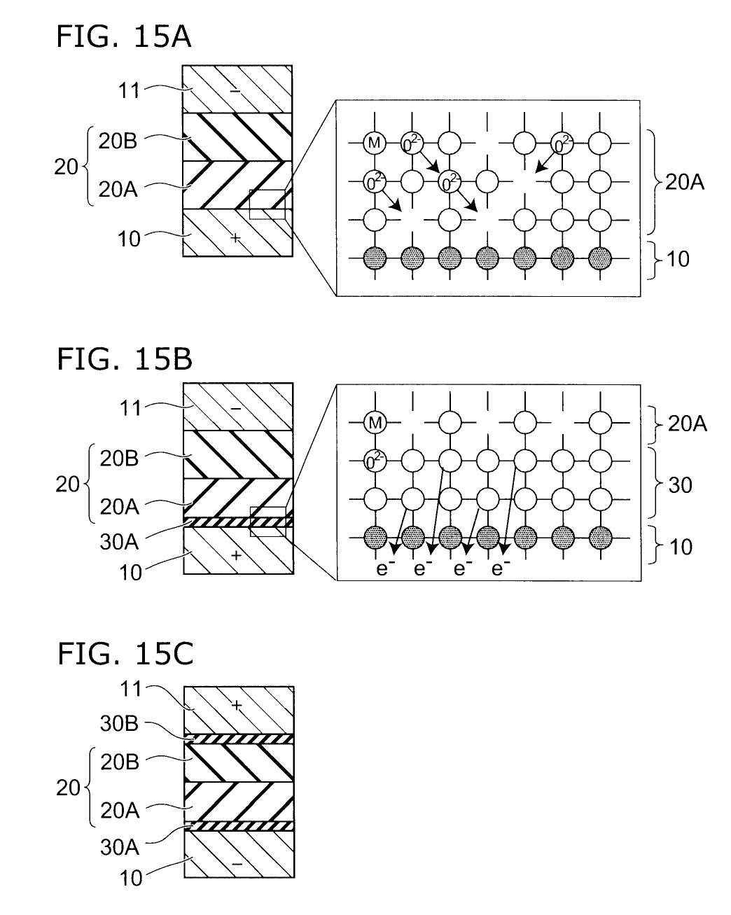

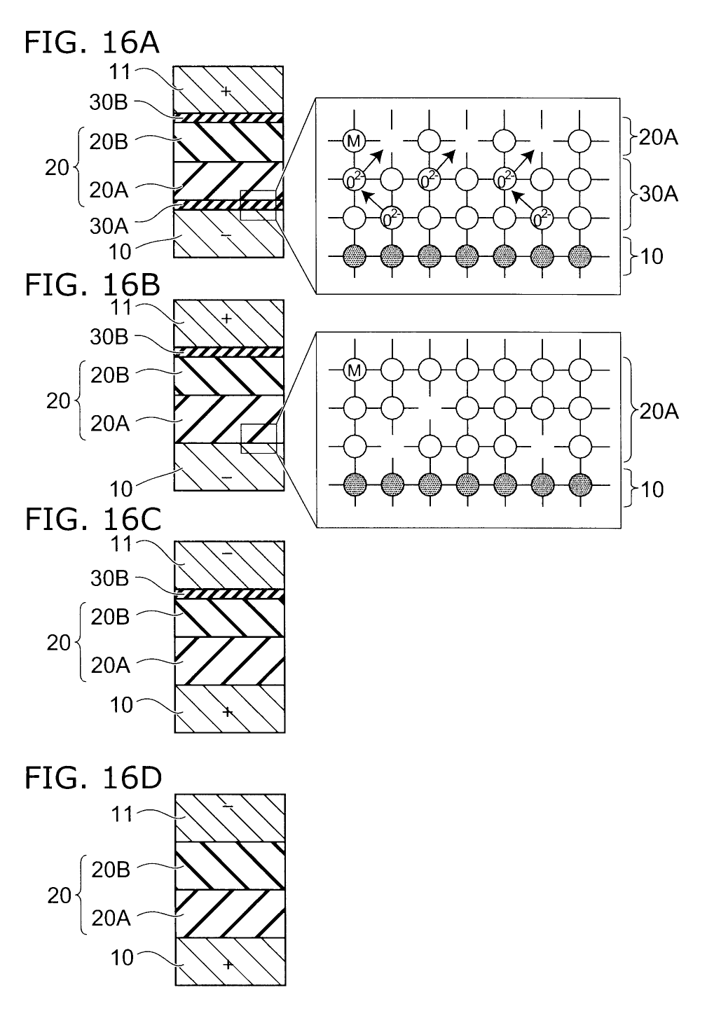

FIGS. 15A to 15C and FIGS. 16A to 16D are schematic cross-sectional views for describing the operation of the memory cell according to the sixth embodiment.

First, the memory cell 105 described above is prepared (FIG. 14). The resistance between the lower electrode film 10 and the upper electrode film 11 in this state is referred to as resistance state 1. After that, when the lower electrode film 10 is made the anode and the upper electrode film 11 is made the cathode as shown in FIG. 15A, oxygen ions in the first memory element unit 20A move via oxygen vacancies due to the electric field, and electrons are released to the lower electrode film 10 that is the anode. Thereby, the memory cell 105 is temporarily stabilized.

The absolute value of the standard Gibbs free energy of formation per one oxygen atom when the lower electrode film 10 changes into an oxide film is smaller than the absolute value of the standard Gibbs free energy of formation per one oxygen atom of the oxide contained in the first memory element unit 20A.

Therefore, the lower electrode film 10 is not oxidized, and oxygen enters oxygen vacancies of the first memory element unit 20A near the lower electrode film 10 as shown in FIG. 15B. Thereby, the memory cell 105 is temporarily stabilized. In other words, the insulating properties of the first memory element unit 20A near the interface between the lower electrode film 10 and the first memory element unit 20A increase, and a third memory element unit 30A having a higher resistance than the first memory element unit 20A is formed between the lower electrode film 10 and the first memory element unit 20A. In this state, the resistance between the lower electrode film 10 and the upper electrode film 11 is higher than in the state of FIG. 15A. The resistance in this state between the lower electrode film 10 and the upper electrode film 11 is referred to as resistance state 2.

Next, as shown in FIG. 15C, when the lower electrode film 10 is made the cathode and the upper electrode film 11 is made the anode, oxygen ions in the second memory element unit 20B move via oxygen vacancies due to the electric field. At this time, electrons are released to the upper electrode film 11. Thereby, the memory cell 105 is temporarily stabilized.

The absolute value of the standard Gibbs free energy of formation per one oxygen atom when the upper electrode film 11 changes into an oxide film is smaller than the absolute value of the standard Gibbs free energy of formation per one oxygen atom of the oxide contained in the second memory element unit 20B.

Therefore, the upper electrode film 11 is not oxidized, and oxygen enters oxygen vacancies of the second memory element unit 20B near the upper electrode film 11 as shown in FIG. 15C. Thereby, the memory cell 105 is temporarily stabilized. In other words, the insulating properties of the second memory element unit 20B near the interface between the upper electrode film 11 and the second memory element unit 20B increase, and a fourth memory element unit 30B having a higher resistance than the second memory element unit 20B is formed between the upper electrode film 11 and the second memory element unit 20B.

In this state, since the third memory element unit 30A and the fourth memory element unit 30B are formed in the memory cell 105, the resistance between the lower electrode film 10 and the upper electrode film 11 is higher than in the state of FIG. 15B. The resistance between the lower electrode film 10 and the upper electrode film 11 in this state is referred to as resistance state 3.

Next, as shown in FIG. 16A, the state where the lower electrode film 10 forms the cathode and the upper electrode film 11 forms the anode is continued. Alternatively, a voltage larger than that in the state of FIG. 15C is applied between the lower electrode film 10 and the upper electrode film 11. Then, as shown in FIG. 16B, oxygen in the third memory element unit 30A formed between the lower electrode film 10 and the first memory element unit 20A is ionized, and oxygen ions move into the first memory element unit 20A due to the electric field.

Thereby, the third memory element unit 30A disappears. As a consequence, the resistance between the lower electrode film 10 and the upper electrode film 11 becomes lower than that in the state of FIG. 16A. The resistance in this state between the lower electrode film 10 and the upper electrode film 11 is referred to as resistance state 4.

Next, as shown in FIG. 16C, when the lower electrode film 10 is made the anode and the upper electrode film 11 is made the cathode, oxygen in the fourth memory element unit 30B is ionized and moves into the second memory element unit 20B due to the electric field. Thereby, the fourth memory element unit 30B disappears (see FIG. 16D). As a consequence, the resistance between the lower electrode film 10 and the upper electrode film 11 becomes lower than that in the state of FIG. 16C. In this state, the third memory element unit 30A and the fourth memory element unit 30B do not exist, and the resistance between the lower electrode film 10 and the upper electrode film 11 is in resistance state 1. That is, the memory cell 105 returns to the initial state.

Thus, the memory cell 105 can ensure resistance states 1 to 4 to enable multiple-valued operation.

In the memory cell 105, by appropriately changing the combination of the materials of the lower electrode film 10, the upper electrode film 11, the first memory element unit 20A, and the second memory element unit 20B, some latitude is allowed in the operation of the memory cell 105.

For example, when the lower electrode film 10 of the memory cell 105 that is in resistance state 1 is made the anode, the upper electrode film 11 is made the cathode, and a voltage is applied to the electrodes, the third memory element unit 30A is formed at the interface between the lower electrode film 10 and the first memory element unit 20A. Thereby, the memory cell 105 changes from resistance state 1 to resistance state 2 (see FIG. 15B).

Next, when the lower electrode film 10 is made the cathode, the upper electrode film 11 is made the anode, and a voltage is applied to the electrodes, oxygen in the third memory element unit 30A formed in the above way is ionized, and oxygen ions move from the third memory element unit 30A to the first memory element unit 20A due to the electric field to cause the third memory element unit 30A to disappear. That is, the memory cell 105 returns to the previous first memory element unit 20A, and returns to resistance state 1 (see FIG. 14).

Next, the time in which the lower electrode film 10 forms the cathode and the upper electrode film 11 forms the anode is continued, or a larger voltage is applied between the lower electrode film 10 and the upper electrode film 11. Thereby, the fourth memory element unit 30B is formed between the upper electrode film 11 and the second memory element unit 20B. That is, the resistance cell 105 changes from resistance state 1 to resistance state 4 (see FIG. 16B).

Next, the lower electrode film 10 is made the anode, the upper electrode film 11 is made the cathode, and the voltage is set to a level at which oxygen ions in the fourth memory element unit 30B between the upper electrode film 11 and the second memory element unit 20B do not move. Thereby, the third memory element unit 30A is further formed at the interface between the lower electrode film 10 and the first memory element unit 20A. That is, the memory cell 105 changes from resistance state 4 to resistance state 3 (see FIG. 15C). Thus, some latitude is provided in the control of the resistance state of the memory cell 105 in accordance with the combination of the material of the memory cell 105.

Also structures in which the first memory element film 20 is formed of a single layer are included in the sixth embodiment. In this case, the memory cell 105 can have three resistance states.

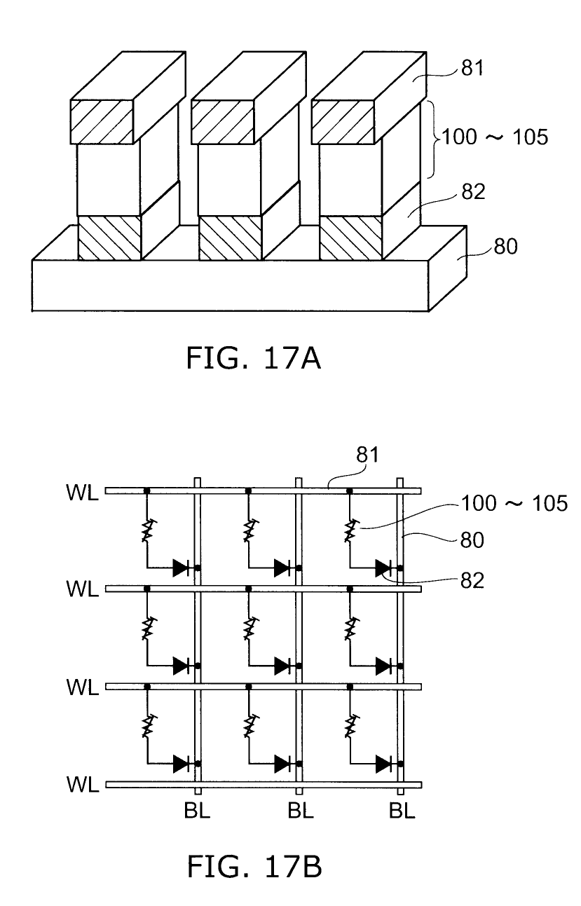

FIGS. 17A and 17B show the structure of a memory cell array of a nonvolatile memory device in which any of the memory cells 100 to 105 described above is mounted.

FIG. 17A is a schematic perspective view of the memory cell array, and FIG. 17B shows an equivalent circuit thereof.

As shown in FIGS. 17A and 17B, each of one of the memory cells 100 to 105 is provided at the intersection of each of bit lines 80 that are lower interconnections and each of word lines 81 that are upper interconnections. The bit line 80 is electrically connected to the lower electrode film 10 of the memory cells 100 to 105. The word line 81 is electrically connected to the upper electrode film 11 of the memory cells 100 to 105. A rectifying element 82 is interposed between the bit line 80 and the memory cells 100 to 105.

Of the memory cells 100 to 105, in the memory cell 101, the memory cell 101 itself exhibits rectifying properties. As shown in FIGS. 17A and 17B, to ensure the rectifying properties of the memory cell 101 more, the rectifying element 82 of an external attachment type may be interposed between the bit line 80 and the lower electrode film 10 of the memory cells 100 to 105, or between the word line 81 and the upper electrode film 11 of the memory cells 100 to 105.

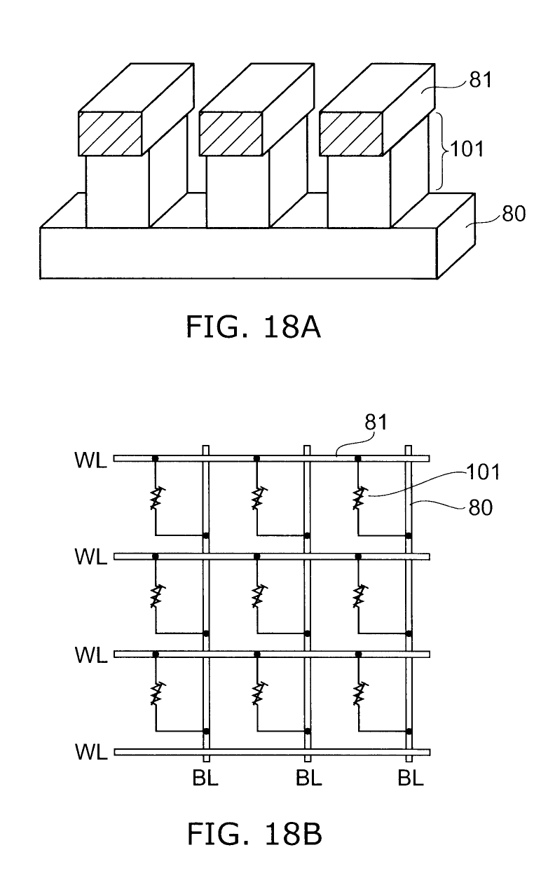

FIGS. 18A and 18B show another structure of the memory cell array in which the memory cell 101 is mounted.

FIG. 18A is a schematic perspective view of the memory cell array, and FIG. 18B shows an equivalent circuit thereof.

As shown in FIGS. 18A and 18B, each of the memory cells 101 is provided at the intersection of each of the bit lines 80 and each of the word lines 81. The rectifying element 82 is not provided in the memory cell array. This is because the memory cell 101 itself exhibits rectifying properties. In this case, the lower electrode film 10 of the memory cell 101 is directly connected to the bit line 80.

In the nonvolatile memory device of the embodiment, by applying a voltage between the lower electrode film 10 and the upper electrode film 11, a high resistance layer with a uniform thickness can be formed between the electrode film and the memory element film. In the nonvolatile memory device of the embodiment, a filament that is a current path does not need to be formed in the memory element film. Thereby, an operation of what is called forming is omitted. The operation called forming takes a relatively long time. Since the forming operation is omitted, the embodiment is low cost and excellent in productivity.

Furthermore, the embodiment provides a memory cell exhibiting rectifying properties even without providing an external rectifying element. This solves the problem that filament-using resistance variable elements have not been able to have rectifying properties by itself. Furthermore, since the memory cell has rectifying properties even without providing an external rectifying element outside the memory cell, the costs of the nonvolatile memory device is decreased as well. Furthermore, since no external rectifying element is provided, the aspect ratio of the stacked film structure at the cross point of the bit line 80 and the word line 81 is more reduced. Furthermore, the manufacturing processes for the memory cell are more simplified. In addition, the mechanical strength of the memory cell is increased.

Furthermore, in the embodiment, the oxygen concentration in the memory element film is stabilized, and the resistance value of the high resistance state of the memory cell is stabilized. Thereby, a significant difference occurs in current value between when the memory cell is in the high resistance state and when in the low resistance state, and the driving (writing and reading) of the memory cell can be stably performed.

Moreover, in the embodiment, a single memory cell can form a plurality of resistance states to enable multiple-valued operation. Therefore, the capacity of the memory cell can be further increased.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A nonvolatile memory device comprising a memory cell including a stacked film structure,
the stacked film structure being capable of maintaining
a first state including:
a lower electrode film;
a first memory element film provided on the lower electrode film and containing a first oxide; and
an upper electrode film provided on the first memory element film or a second state including:
the lower electrode film;
the first memory element film provided on
the lower electrode film;
a second memory element film provided on the first memory element film and containing a second oxide; and
the upper electrode film provided on the second memory element film,
an absolute value of a standard Gibbs free energy of formation per one oxygen atom when the lower electrode film or the upper electrode film changes into an oxide film being smaller than an absolute value of a standard Gibbs free energy of formation per one oxygen atom of the first oxide contained in the first memory element film,
an absolute value of a standard Gibbs free energy of formation per one oxygen atom of the second oxide contained in the second memory element film being larger than an absolute value of a standard Gibbs free energy of formation per one oxygen atom when the upper electrode film changes into the oxide film,
a concentration of oxygen contained in the second memory element film being higher than a concentration of oxygen contained in the first memory element film,
a resistance between the lower electrode film and the upper electrode film in the second state being higher than a resistance between the lower electrode film and the upper electrode film in the first state.

2. The device according to claim 1, wherein
the stacked film structure further includes an electric field control film containing a third oxide between the lower electrode film and the first memory element film,
a dielectric constant of the first memory element film is higher than a dielectric constant of the electric field control film,
a band gap of the electric field control film is wider than a band gap of the first memory element film,
an absolute value of a standard Gibbs free energy of formation per one oxygen atom of the first oxide contained in the first memory element film is smaller than an absolute value of a standard Gibbs free energy of formation per one oxygen atom of the third oxide contained in the electric field control film, and
an absolute value of a standard Gibbs free energy of formation per one oxygen atom of the third oxide contained in the electric field control film is larger than an absolute value of a standard Gibbs free energy of formation per one oxygen atom when the lower electrode film changes into the oxide film.

3. The device according to claim 1,
further comprising an oxygen supply layer containing a conductive oxide between the upper electrode film and the first memory element film or between the upper electrode film and the second memory element film,
an absolute value of a standard Gibbs free energy of formation per one oxygen atom of the conductive oxide contained in the oxygen supply layer being smaller than an absolute value of a standard Gibbs free energy of formation per one oxygen atom of the first oxide contained in the first memory element film.

4. The device according to claim 1,
further comprising an insulating layer containing a fourth oxide between the upper electrode film and the first memory element film or between the upper electrode film and the second memory element film,
a chemical composition of the fourth oxide being near to a stoichiometric ratio as compared to a chemical composition of the first oxide,
an absolute value of a standard Gibbs free energy of formation per one oxygen atom of the fourth oxide contained in the insulating layer being larger than an absolute value of a standard Gibbs free energy of formation per one oxygen atom of the first oxide contained in the first memory element film,
an absolute value of a standard Gibbs free energy of formation per one oxygen atom of the fourth oxide contained in the insulating layer being larger than an absolute value of a standard Gibbs free energy of formation per one oxygen atom when the upper electrode film changes into the oxide film.

5. The device according to claim 1, wherein
the first memory element film includes:
a first memory element unit on the lower electrode film side; and
a second memory element unit on the upper electrode film side,
an absolute value of a standard Gibbs free energy of formation per one oxygen atom when the lower electrode film changes into an oxide film is smaller than an absolute value of a standard Gibbs free energy of formation per one oxygen atom of an oxide contained in the first memory element unit, and
an absolute value of a standard Gibbs free energy of formation per one oxygen atom when the upper electrode film changes into an oxide film is smaller than an absolute value of a standard Gibbs free energy of formation per one oxygen atom of an oxide contained in the second memory element unit.

6. The device according to claim 1,
further comprising:
an upper interconnection connected to the upper electrode film of the memory cell; and
a lower interconnection connected to the lower electrode film of the memory cell,
the lower electrode film being directly connected to the lower interconnection.

7. The device according to claim 6, further comprising a rectifying element between the memory cell and the upper interconnection or between the memory cell and the lower interconnection.

8. The device according to claim 1, wherein
the first memory element film is formed of an oxide film of two or more metal elements and
the second memory element film is formed of an oxide film of a metal element having a largest absolute value of a standard Gibbs free energy of formation per one oxygen atom out of the two or more metal elements.

9. The device according to claim 1, wherein the second memory element film contains an oxide of a metal element contained in the first memory element film.

10. The device according to claim 1, wherein the second memory element film has a composition near to a stoichiometric ratio as compared to the first memory element film.

11. The device according to claim 1, wherein an oxygen concentration of the first memory element film in the second state is lower than an oxygen concentration of the first memory element film in the first state.

12. The device according to claim 1, wherein a thickness of the second memory element film is controlled by a voltage applied between the upper electrode film and the lower electrode film.

13. The device according to claim 1, wherein the second memory element film has a film thickness of 3 nanometers or less.

14. The device according to claim 2, wherein a material of the first memory element film contains a high-k material and a material of the electric field control film contains a low-k material.

15. The device according to claim 2, wherein a tunnel current flows through the electric field control film.

16. The device according to claim 8, wherein
a material of the first memory element film contains at least two kinds of metals selected from the group consisting of titanium (Ti), tantalum (Ta), niobium (Nb), tungsten (W), iron (Fe), and copper (Cu) and
a material of the second memory element film contains one or more kinds of metals selected from the group consisting of titanium oxide (TiO₂), tantalum oxide (Ta₂O₅), and niobium oxide (Nb₂O₅).

17. The device according to claim 8, wherein a material of the first memory element film contains TiOₓ doped with Nb and a material of the second memory element film contains TiO₂.

18. The device according to claim 3, wherein a material of the first memory element film contains NbOₓ (x<2.5) and the oxygen supply layer contains RuOₓ (x<2).

19. The device according to claim 4, wherein the first memory element film is NbOₓ (x<2.5), the insulating layer is Al₂O₃, and the upper electrode film is TiN.

20. The device according to claim 4, wherein a resistivity of the insulating layer is higher than a resistivity of the first memory element film or a resistivity of the second memory element film.
